(19) United States
(12) Patent Application Publication
(10) Pub. No.: US 2021/0187706 A1
(43) Pub. Date: Jun. 24, 2021

(54) DRILLING DEVICE WITH OPTIMIZED ACTUATION

(71) Applicant: ETABLISSEMENTS GEORGES RENAULT, Saint Herblain (FR)

(72) Inventor: Kevin Poirier, Nantes (FR)

(21) Appl. No.: 17/130,588

(22) Filed: Dec. 22, 2020

(30) Foreign Application Priority Data
Dec. 24, 2019 (FR) 1915567

(51) Int. Cl. B25B 21/00; B25F 5/02

(52) U.S. Cl. CPC B25B 21/008; B25F 5/02

(57) ABSTRACT

A portable drilling device or screw driving device, including: an electric motor; an autonomous or wired electric supply to the motor; an actuating trigger; a controller, which commands the motor as a function of the position of the trigger; the trigger being mobile between at least: a resting position in which the motor is at a stop; a position of total actuation in which the motor is driven by the controller according to a first predetermined rotation frequency; wherein the trigger can take a predetermined intermediate position is situated between the resting and actuating positions and the motor being driven by the controller according to a second predetermined rotation frequency. An elastic return counters movement of the trigger from the resting position towards the position of total actuation, and a first fixed magnetic attraction counters movement of the trigger between the intermediate position and the position of total actuation.

### 1. FIELD OF THE INVENTION

The field of the invention is that of portable drilling tools.

The invention relates more particularly to the trigger for actuating such tools.

### 2. PRIOR ART

Portable drilling tools are commonly used in various fields such as, for example, the aeronautics industry.

Aeronautical production has to cope with three main technical challenges.

A first challenge results from the fact that aircraft today are constituted by numerous materials, such as for example carbon composite materials, aluminum or aluminum-lithium alloy, titanium and steel. These different materials have different cutting conditions and their stacking in aircraft structures complicates the cutting parameters. Thus, to make sure that a high level of quality of the finished parts is maintained, a drilling operation must sometimes be sub-divided into several operations. This sequencing increases the total cost of manufacture of the aircraft, whether it is because of the multiplicity of drilling operations, or because of the increased precision of positioning of the holes on the various elements to be drilled as well as the time needed to handle the parts to be drilled.

A second challenge results from the fact that a large number of drilling operations are carried out by hand. The structural parts of the aircraft are held in position by riveting or bolting. In addition to the very high requirements of precision related to the holding of the structure during flight, there is the fact that these systems for holding parts in position requires the making of a very large number of holes, entailing drilling operations of the order of 750,000 to 1,500,000 per aircraft. A portion of these drilling operations is carried out with automatic drilling units (fixed to drilling templates or patterns that fulfil the template function) but there is still a large amount of drilling carried out by hand-held drills because of space requirements or the cost of tools. This type of drilling can amount to about 70% of the drillings carried out in a production site.

A third challenge results from the fact that the competitive development of the aeronautical sector imposes new requirements in terms of production rates and an improvement of productivity. The firm Airbus, in early 2016, had plans to produce 45 A350 aircraft in 2016, 80 in 2017, and 120 in 2018.

The need to increase production rates makes it necessary to reduce the time dedicated to each operation. The operation of drilling by hand is a complex one that depends greatly on the qualifications and competence of the operator and that can entail numerous problems of non-compliance with requisite quality (i.e. sub-standard maintenance). These instances of sub-standard maintenance can be because of problems of surface conditions, burrs, scaling, delamination, drifts in values of diameter, shapes and orientation, etc. These factors lead to a reduction of productivity and major costs (it costs, on average, €1,200 to redo a hole, and this amounts to costs of millions of Euros per year).

For example, to avoid delamination during the drilling of carbon, it is necessary to be able to drill with a very high rotation speed. When drilling an element comprising a stack of several materials, it must also be possible to drill titanium at low speeds to avoid heating that could damage the material and cause rapid wear and tear of the cutting tool. The issue today therefore is to be able to adjust the cutting parameters as efficiently as possible for each specific drilling phase.

Aircraft manufacturers therefore are now demanding means to assist in the operation and to make it more reliable in order to reduce sub-standard maintenance and thus increase productivity.

In the aeronautics industry, there are known ways of making drillings by hand using hand-operated pneumatic drills. These drills were designed at a time when the drilling of aluminum alloys was predominant. These drills propose only one drilling speed. When a stack of several layers of different materials has to be drilled, a drill is therefore chosen for which the rotation frequency corresponds to that of the material of the stack requiring the lowest rotation frequency. For example, aluminum and titanium require rotation frequencies for the cutting tool respectively equal to 4,500 rotations per minute and 800 rotations per minute. A stack comprising aluminum and titanium will therefore be drilled using a drill rotating at 800 rotations per minute. This choice thus penalizes productivity and entails lower quality for a material that is not drilled with the optimal parameters.

Besides, the air nozzle of the drill can also be cumbersome when making certain holes that have complicated accessibility.

There are also known ways of making drill holes using electric drilling units with controlled cutting parameters. These drilling units are bulky and fixed (therefore not hand-operated) and are suited for drillings that have greater diameter and are easily accessible.

Drilling units with controlled cutting parameters do not meet the need for portable tools. These are tools intended to be fixed to a frame during the drilling action and are therefore not easy to handle.

The technical limits of the prior art for these pneumatic and electric drills therefore mean that it is not possible to respond to developments in the requirements of productivity and of flexibility of the tools for production in the aeronautics sector.

The present invention is therefore aimed at bringing progress in the prior art for hand-operated drills in order to meet present-day technical challenges dictated by the aeronautics industry.

### 3. SUMMARY OF THE INVENTION

To this end, an exemplary embodiment of the invention proposes a portable drilling device or screw driving device, comprising at least:
an electric motor;
autonomous or wired means for supplying electricity to said motor;
an actuating trigger;
means for commanding said motor as a function of the position of said trigger; said trigger being mobile between at least:
a resting position in which said motor is at a stop;
a position of total actuation in which said motor is driven by said means for commanding according to a first predetermined rotation frequency;

said trigger can take a predetermined intermediate position in which it is situated between said resting and actuating positions and said motor is driven by said means for commanding according to a second predetermined rotation frequency.

According to an exemplary embodiment of the invention, such a device comprises elastic return means that counter the movement of said trigger from its resting position towards its position of total actuation, and first fixed means of magnetic attraction countering the movement of said trigger between its intermediate position and its position of total actuation.

The implementation of the means of magnetic attraction therefore constitutes a magnetic stop element for stopping in the intermediate position in which the tool works according to a predetermined rotation frequency. This magnetic stop can be inhibited when the operator actuates the trigger sufficiently to counter the effort of magnetic attraction that it exerts on the trigger and thus place the trigger in the total actuating position in which the tool works at another rotation frequency.

This implementation thus enables an operator to efficiently perceive the position of the trigger and especially its passage from the intermediate position to the total actuation position. He can thus have knowledge, reliably and in a simple but efficient way, of the rotation frequency at which he is applying the tool.

An exemplary embodiment of the invention therefore provides a portable electric drilling tool offering two rotation frequencies and provided with an ergonomic and intuitive actuation system ensuring that the operator will know the frequency at which his tool is working.

A drilling device according to an exemplary embodiment of the invention is therefore flexible and ergonomic and therefore enables high-quality drillings of multilayer elements with a high level of productivity.

According to one possible characteristic, said trigger is mobile in translation along an axis to pass from one of its positions to the other.

According to one possible characteristic, said trigger is fixedly attached to one extremity of a shaft mounted inside a ferromagnetic ring, said shaft and said ring being mobile in translation relatively to each other along said shaft, said ring comprising a first extremity against which said trigger is able to take support and a second extremity able to come into contact with said means of magnetic attraction, said trigger being situated:
at a distance from said first extremity in the positions comprised between the resting position and the intermediate position,
in contact with said first extremity in the positions comprised between the intermediate position and the position of total actuation,
said first means of magnetic attraction being sized so that said second extremity:
remains in contact with said fixed means of magnetic attraction when said trigger is situated in the positions between the resting position and the intermediate position,
is situated at a distance from said fixed means of magnetic attraction when said trigger is situated in the positions between the intermediate position and the position of total actuation.

According to one possible characteristic, a device according to an exemplary embodiment of the invention comprises second means of magnetic attraction positioned at the extremity of said trigger configured to come into contact with said first extremity of said ring.

According to one possible characteristic, said first and second means of magnetic attraction are annular, said ring and said shaft passing into the interior of the first means of magnetic attraction and said shaft passing into the interior of the second means of magnetic attraction.

According to one possible characteristic, a device according to an exemplary embodiment of the invention comprises a support for said first means of magnetic attraction, said support comprising a first borehole in which said ring is mounted slidingly and a second borehole forming a clear space within which the extremity of said trigger designed to come into contact with said ring can be introduced when it is moved from its resting position to its position of total actuation.

According to one possible characteristic, said return means comprise a compression spring interposed between said support and said trigger, said spring having a first extremity housed in said second borehole and another extremity housing the extremity of said trigger designed to come into contact with said ring.

According to one possible characteristic, a device according to an exemplary embodiment of the invention comprises means for determining the position of said trigger, said means for determining comprising a first Hall effect sensor and a detection magnet fixedly attached to said trigger.

According to one possible characteristic, said means for determining the position of said trigger comprise a second Hall effect sensor, said first and second sensors being distant from each other along the trajectory of movement of said trigger

According to one possible characteristic, said first Hall effect sensor is of the analog type and said second Hall effect sensor is of a digital or analog type.

According to one possible characteristic, said first and second rotation frequencies are of the same sign or are of opposite signs.

According to one possible characteristic, said first and second rotation frequencies have equal or different standards.

### 4. DESCRIPTION OF THE FIGURES

Other features and advantages of the invention shall appear from the following description of particular embodiments, given by way of simple, illustratory and non-exhaustive examples, and from the appended drawings, of which:

FIG. 1 illustrates a cross-section view of the drilling device;

FIG. 2 illustrates a partial side view of the device of FIG. 1;

FIG. 3 illustrates a detailed view of the trigger of the device of FIG. 2;

FIG. 4 illustrates an exploded view of the trigger of FIG. 3;

FIG. 5 illustrates the trigger of FIG. 4 in a resting position;

FIG. 6 illustrates the trigger of FIG. 4 in an intermediate position;

FIG. 7 illustrates the trigger of FIG. 4 in a position of total actuation;

FIG. 8 illustrates the trigger of the device without magnet for returning to the resting position;

FIG. 9 illustrates the trigger of a device without magnet for returning to the intermediate position;

FIG. 10 illustrates the trigger of a device without a magnet for returning to the position of total actuation;

FIG. 11 illustrates an example of a variation of the signal of the first sensor of a double sensor device;

FIG. 12 illustrates an example of a variation of the signal of the second sensor of a double sensor device;

FIG. 13 illustrates the variation of the force applied by the operator on the trigger during its actuation.

### 5. DESCRIPTION OF PARTICULAR EMBODIMENTS

5.1. Architecture

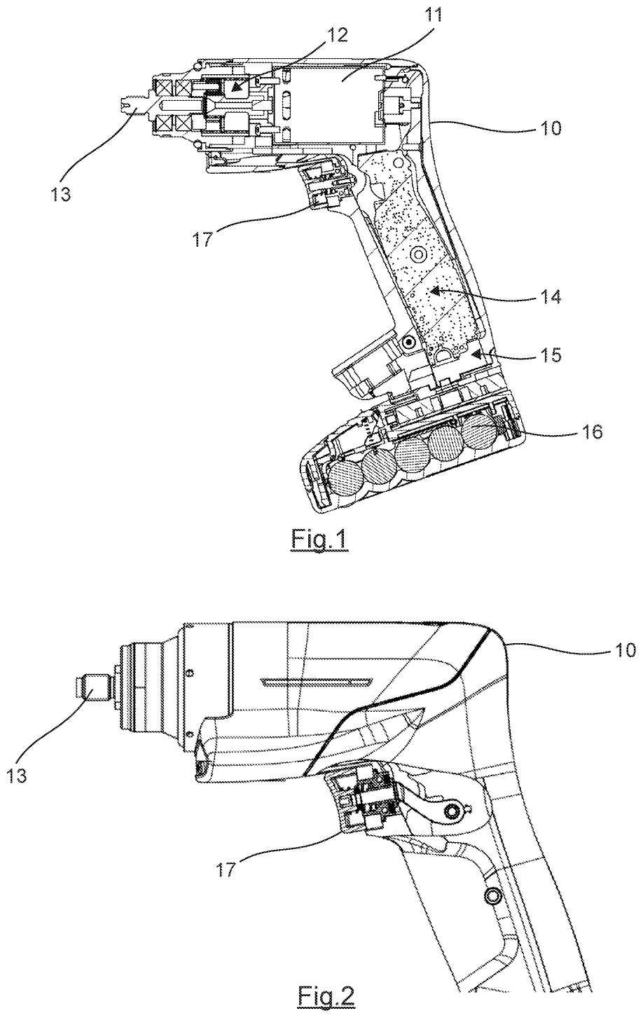

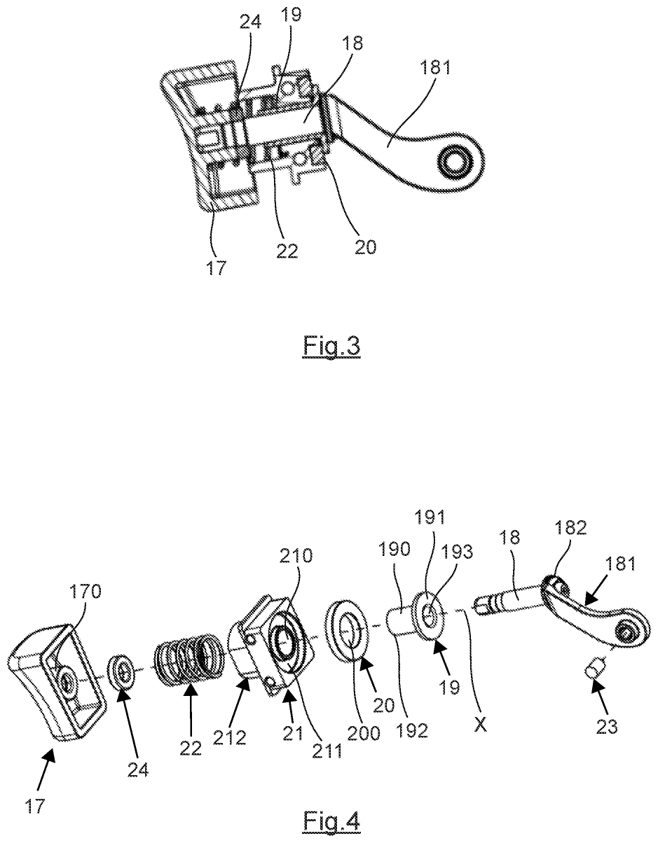

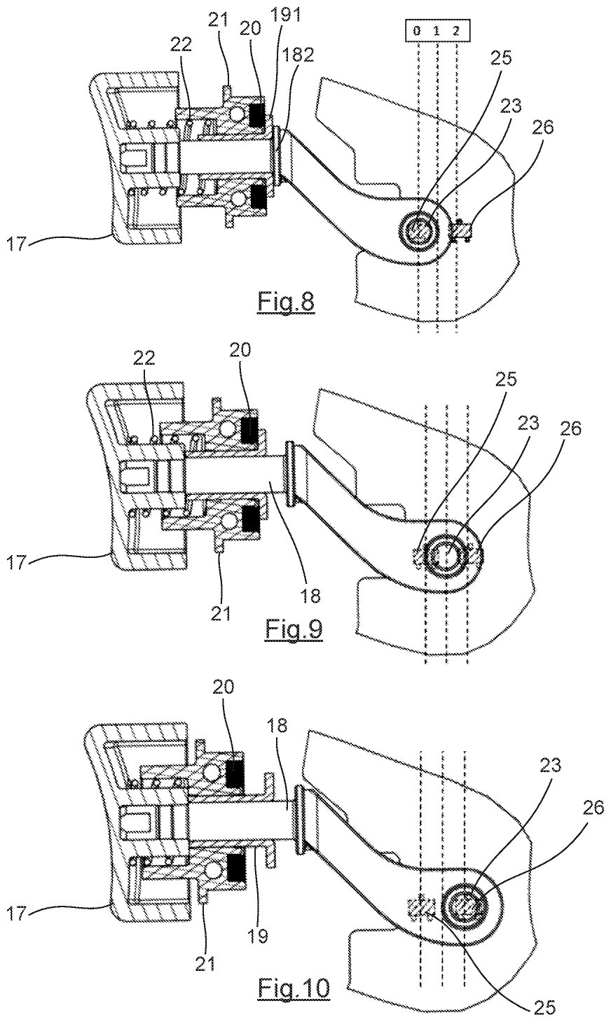

Referring to FIGS. 1 to 13, we present an example of a drilling device according to an exemplary embodiment of the invention. It could also be a screw driving device capable of performing the screw driving function or the screwing and unscrewing functions.

As represented, such a device comprises a casing 10. This casing is herein of the pistol grip type (the axis of the grip forms a non-zero angle with the axis of the rotation of the terminal member). It could also be a longitudinal casing of which the axis of the grip is parallel with or coincides with the axis of rotation of the terminal member or it could be any other type of casing.

This casing 10 houses an electric motor 11. It is preferably a permanent magnet synchronous motor. It could however be any other type of electric motor.

The output shaft of the motor is connected to the input of a transmission 12, the output of which is connected to a terminal member 13 can be driven in rotation via the motor and the transmission.

The terminal member is designed to carry a cutting tool used to carry out a drilling operation.

The casing houses control means 14 to control the motor. These control means, known per se and therefore not described in detail, are used to regulate the motor speed.

The casing houses independent electrical power supply means for the motor. These means herein include an inverter 15 and a battery 16. It could be any other type of independent power supply means such as a capacitor or the like. Alternatively, it be a wired electrical power supply means.

The device comprises an actuation trigger 17.

The trigger 17 is fixedly attached to one extremity of a shaft 18 made of a non-magnetic material such as for example bronze or the like.

The shaft 18 is mounted within a ring 19 made of ferromagnetic material.

The ring 19 comprises a cylindrical portion 190 extended by a circular skirt 191.

The shaft 18 and the ring 19 are mobile in translation relatively to each other along an axis X corresponding to the axis of translation of the trigger 17.

The ring 19 comprising a first extremity 192 against which the trigger 17 is can come to rest and a second extremity, herein constituted by the skirt 191, can come into contact with first means of magnetic attraction that herein comprise an annular magnet 20 traversed by a central aperture 200. This magnet, also called a detent magnet could have any other suitable shape.

The magnet 20 is mounted on a support 21 in a housing 211, provided for this purpose, at a first extremity. The support 21 is fixedly attached in the casing and is traversed by a borehole 210. It comprises a second housing 212 at its other extremity designed to house an extremity of an elastic return means 22 herein comprising a compression spring. Any other suitable elastic return means could be used such as a leaf spring, a spiral spring, a tension (or draw) spring or the like.

The other extremity of the spring 22 is placed around a protrusion 170 having a complementary shape made in the trigger 17.

The shaft 18 has a skirt 182 at one of its extremities and is extended by a plate 181 bearing a detection magnet 23.

The cylindrical portion 190 of the ring 19 is housed in the borehole 210 of the support. The shaft 18 is mounted slidingly within the drill hole 193 of the ring 19.

Second magnetic attraction means comprising a return magnet 24 are fixedly attached to the extremity of the protrusion 170. As an alternative, it is fixedly attached to the shaft 18. This magnet is optional. It too has an annular shape, but it could have any other suitable shape.

The trigger is mounted mobile in translation between at least:
a resting position in which the motor is at a stop;
a total actuation position in which the motor is driven by the command means at a first predetermined rotation frequency;
an intermediate position in which it is situated between the resting position and the total actuation position and the motor is driven by the command means at a second predetermined rotation frequency.

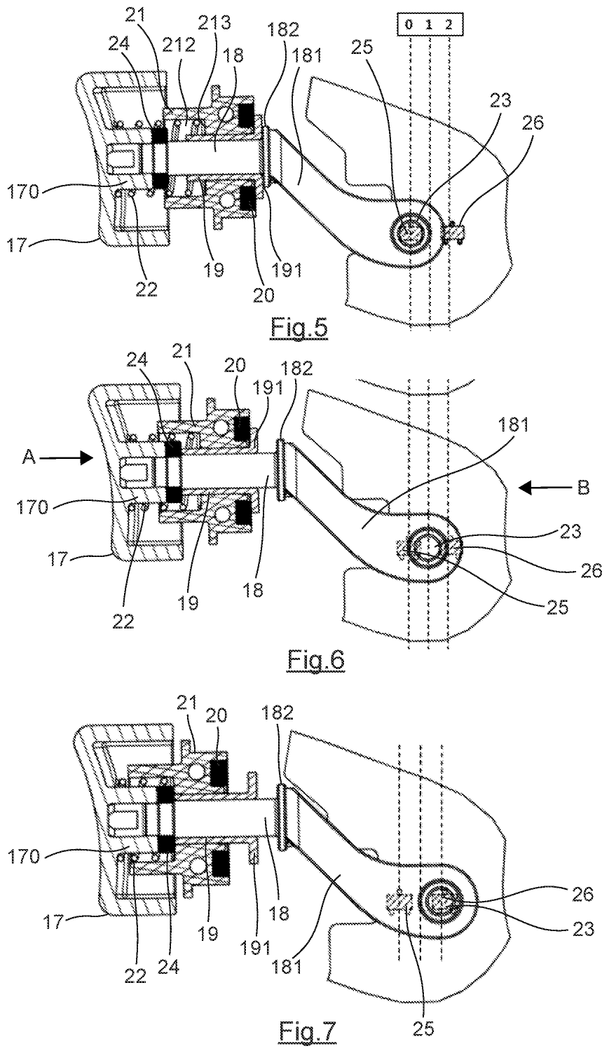

When an operator exerts no force on the trigger 17, the compression spring 22 tends to bring it into its resting position illustrated in FIG. 5.

In the resting position, the trigger 17 is out of the casing to its furthest extent. The skirt 182 of the shaft abuts the skirt of the ring, the skirt 191 of the ring abuts the magnet 20 and the magnet 20 is at a distance from the extremity 192 of the ring 18.

When an operator exerts a force on the trigger along the axis of movement of the trigger towards the interior of the casing (cf. arrow A in FIG. 6), the trigger gets translated against the force of the spring 22 which gets compressed. The shaft 18 slides within the ring 19 and the skirt 182 of the shaft 18 moves away from the magnet 20. The trigger is thus penetrated until the magnet 24 abuts the first extremity 192 of the ring 19. The skirt 191 of the ring stays in contact with the magnet 20. The trigger is thus in its intermediate position.

If the operator wishes to place the trigger in its position of total actuation, he must exert an force on this trigger that is greater along the arrow A. Indeed, this effort must counter the sum of the compression force of the spring 22 and the force of magnetic attraction exerted on the ring by the magnet 20. When the force exerted by the operator to make the trigger penetrate deeper towards its position of total actuation is greater than this sum, the ring 19 gets detached from the magnet 20. The ring 19 and the shaft 18 are then moved by the trigger in translation along the arrow A. This movement is made until the magnet 24 abuts the bottom 213 of the housing 212. The trigger is then in its position of total actuation (cf. FIG. 7).

The ring and the magnet form a magnetic stop for the trigger, the reaching of which corresponds to the intermediate position. The magnet 20 is sized to determine a predetermined force that the operator must exert on the trigger to leave the intermediate position and go towards the position of total actuation. The magnet 20 counters the movement of the trigger at least over an initial portion of its travel in moving between its intermediate position and its position of total actuation.

When the trigger is situated in the position of total actuation, and when the operator releases the trigger, the spring 22 gets relaxed and tends to act on the trigger to move it towards the intermediate position along the arrow B. The axis 28, fixedly attached to the trigger, follows the same motion. Since the extremity 192 of the ring is in contact with the magnet 24, the ring is also driven in translation until its skirt 191 abuts the magnet 20. The operator thus perceives the return of the trigger to the intermediate position. If the operator continues to release the trigger, the spring 22 continues to relax and exert an force great enough to counter the force of magnetic attraction of the magnet 24. The magnet 24 gets detached from the ring 19 which remains resting against the magnet 20. The spring then moves the trigger until the skirt 182 of the shaft 18 abuts the skirt 191 of the ring. The trigger is then in its position of rest.

The magnet 24 then makes it possible, when the operator gently relaxes the trigger while accompanying it to from its position of total actuation towards its position of rest, to perceive the return to the intermediate position. He can thus, if he so wishes, release the trigger in the intermediate position rather than bring it back directly to its resting position.

The magnet 24 is optional and it is possible not to implement it. In this case, the trigger can come into contact with the ring directly. When the magnet 24 is not implemented, it is harder or even impossible for the operator to perceive the return of the trigger to its intermediate position from the position of total actuation.

In this embodiment, it is planned that the magnets 20 and 24 will come directly into contact with the ring on which they must exert their force. It is however possible that this contact will be indirect, i.e., they may be disposed relatively to the ring so as not to transmit their force of magnetic attraction towards it without physical contact.

The annular shape of the magnets 20 and 24 enable them to offer contact surfaces of a shape substantially identical to those of the surfaces of the ring and of the protrusion 170 of the trigger designed to come into contact with them. This enables a better distribution of the force of magnetic attraction transmitted by the magnets to these parts.

The device according to an exemplary embodiment of the invention comprises means for determining the position of the trigger.

These means for determining comprise at least one first sensor 25, preferably analog, the signal of which is illustrated in FIG. 11.

When the trigger is situated in its resting position, the detection magnet 23 is positioned relatively to the first sensor in such a way that the information delivered by the first sensor 25 is smaller than the first predetermined value A.

When the trigger is situated in its position of total actuation, the detection magnet 23 is positioned relatively to the first sensor in such a way that the information delivered by the first sensor 25 is greater than a second predetermined value B.

When the trigger is situated in its intermediate position, the detection magnet 23 is positioned relatively to the first sensor in such a way that the information delivered by the first sensor 25 is comprised between the first and second predetermined values A and B.

The sensor is connected to the command means for commanding the motor which drives and regulates the motor speed, so that:
when the trigger is in its resting position, the motor is not powered and is at a stop;
when the trigger is situated in its intermediate position, the motor rotates at a first predetermined first frequency of rotation V1;
when the trigger is situated in its position of total actuation, the motor rotates at a second predetermined frequency of rotation V2.

The first and second frequencies of rotation may be of the same sign. They can however be of opposite signs, especially but not exclusively when the transmission is of a winch type in which a reversal of the sense of rotation of the motor makes it possible to engage transmission ratios of different values. Transmissions of this type are for example described in the documents FR 3 000 694 and FR 2 913 361.

The first and second rotation frequencies can have equal or different standards.

The means for determining the position of the trigger can, as an alternative, additionally include a second Hall effect sensor 26.

These sensors are distant from each other along an axis substantially parallel to the axis of translation of the trigger.

The first sensor is saturated when the detection magnet is facing it.

The first sensor is preferably of an analog type while the second sensor is preferably of a digital type. The second sensor could however be also of an analog type.

The second sensor 26 is a safety sensor used to make sure of the real position of the trigger or to mitigate a defect in the sensor 25.

A defect in the holding the detection magnet 23 with the plate 181 would entail a signal on the sensor 25 greater than the value B and therefore a setpoint value of rotation frequency V2 whereas the trigger is in the position of rest which means that the setpoint value should be a stopping of the motor.

Similarly, a default on the sensor 25 could give rise to a signal on the sensor 25 greater than the value B and hence, in this case too, a setpoint value of rotation frequency V2 whereas the trigger is in a resting position which means that the setpoint value should be a stopping of the motor.

The first sensor alone is therefore not sufficient to determine the position of the trigger or to mitigate an electronic defect.

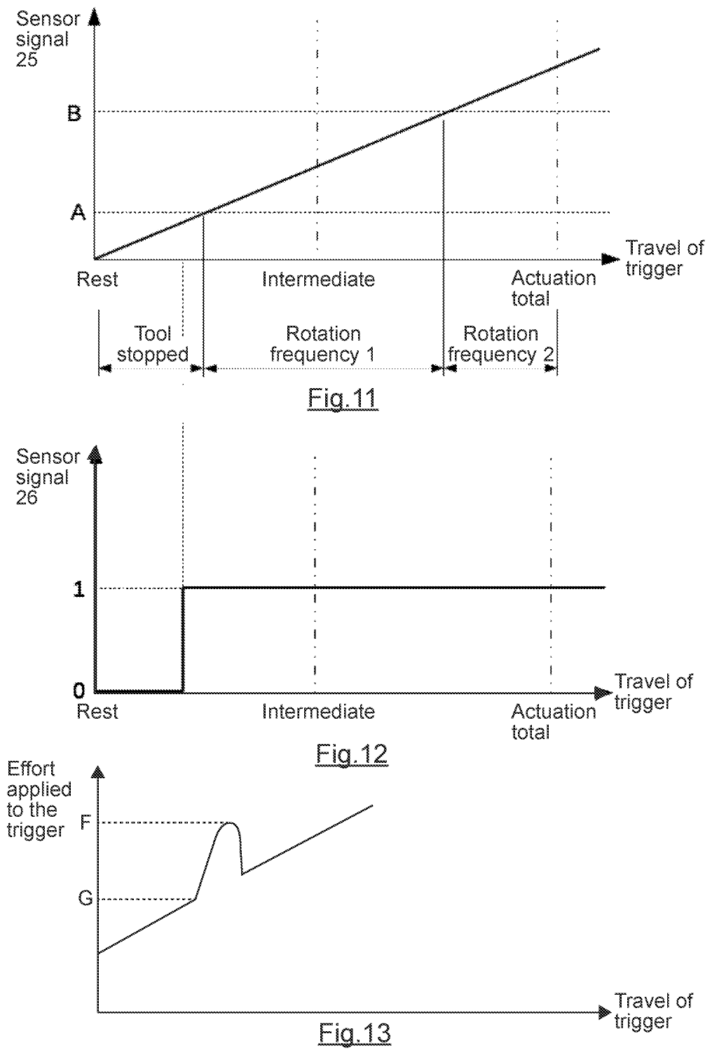

The use of the second sensor makes it possible to cure this problem. To this end, as can be seen in FIG. 12 illustrating the variation of its signal as a function of the position of the trigger, this sensor is sized in such a way that its signal is zero when the trigger is in the resting position and is not zero when the trigger is situated in an intermediate position or in a position of total actuation, and vice versa.

Thus, taking the signals delivered by both sensors into consideration enables the motor control means to define the position of the trigger and to regulate the motor accordingly as well as to mitigate an electronic problem on the sensor 25.

In the example of FIGS. 11 and 12, when the value of the first sensor is smaller than A and when the signal of the second sensor is zero, the trigger is in a resting position. When the value of the first sensor is greater than B and when that of the second sensor is not zero, the trigger is in a position of total actuation. When the value of the first sensor is between A and B and when that of the second sensor is not zero, the trigger is in an intermediate position.

The first rotation frequency is activated around the intermediate position, i.e., the motor is regulated at the first frequency of rotation on a range around the intermediate position (the first rotation frequency is activated slightly before the intermediate position is reached and is maintained slightly beyond the intermediate position). The second rotation frequency is activated slightly before the position of total actuation is reached and is maintained slightly after the trigger leaves this position towards the intermediate position.

This principle is illustrated in FIG. 11.

The combined implementation of the return spring 22 and the detent magnet 20 enables the operator to perceive the passage of the trigger into the intermediate position.

FIG. 13 illustrates variations of the effort applied by an operator to the trigger during its actuation as a function of the travel of the trigger.

For the operator to accurately perceive the passage of the trigger into the intermediate position, the ratio of the values F/G must be preferably comprised between 1.2 and 10.

An exemplary embodiment of the present application provides an efficient solution to at least certain of the different problems discussed above.

In particular, at least one embodiment procures a hand-operated electric drilling device that is flexible in terms of rotation frequencies.

In particular, at least one embodiment provides such a device that offers the possibility of choosing between several rotation frequencies.

At least one embodiment provides such a device that enables its user to efficiently perceive the rotation frequency at which he or she applies it.

At least one embodiment provides such a device that is simple and/or robust.

At least one embodiment provides such a device that is reliable and efficient.

Although the present disclosure has been described with reference to one or more examples, workers skilled in the art will recognize that changes may be made in form and detail without departing from the scope of the disclosure and/or the appended claims.

1. A portable drilling device or screw driving device, comprising at least:
an electric motor;
autonomous or wired electrical supply for supplying electricity to said motor;
an actuating trigger, wherein the actuating motor is controlled as a function of a position of said trigger, said trigger being mobile between at least:
a resting position in which said motor is at a stop;
a position of total actuation in which said motor is driven according to a first predetermined rotation frequency; and
a predetermined intermediate position in which the trigger is situated between said resting and actuating positions and said motor is driven according to a second predetermined rotation frequency;
an elastic return that counters the movement of said trigger from the resting position towards the position of total actuation; and
a first fixed magnet supplying a first magnetic attraction countering the movement of said trigger between the intermediate position and the position of total actuation.

2. The device according to claim 1 wherein said trigger is mobile in translation along an axis to pass from one of the positions to another of the positions.

3. The device according to claim 2 wherein said trigger is fixedly attached to one extremity of a shaft mounted inside a ferromagnetic ring, said shaft and said ring being mobile in translation relatively to each other along said shaft, said ring comprising a first extremity against which said trigger is able to take support and a second extremity able to come into contact with said means of magnetic attraction, said trigger being situated:
at a distance from said first extremity in positions comprised between the resting position and the intermediate position,
in contact with said first extremity in positions comprised between the intermediate position and the position of total actuation,
said first fixed magnet being sized so that said second extremity:
remains in contact with said first fixed magnet when said trigger is situated in the positions between the resting position and the intermediate position;
is situated at a distance from said first fixed magnet when said trigger is situated in the positions beyond the intermediate position up to the position of total actuation.

4. The device according to claim 3 comprising a second magnet supplying a second magnetic attraction positioned at the extremity of said trigger and configured to come into contact with said first extremity of said ring.

5. The device according to claim 4 wherein said first and second fixed magnets are annular, said ring and said shaft passing into the interior of the first fixed magnet and said shaft passing into the interior of the second fixed magnet.

6. The device according to claim 5 comprising a support for said first fixed magnet, said support comprising a first borehole in which said ring is mounted slidingly and a second borehole forming a clear space within which the extremity of said trigger designed to come into contact with said ring can be introduced when the trigger is moved from the resting position to the position of total actuation.

7. The device according to claim 6 wherein said elastic return comprises a compression spring interposed between said support and said trigger, said spring having a first extremity housed in said second borehole and another extremity housing the extremity of said trigger designed to come into contact with said ring.

8. The device according to claim 1, comprising first Hall effect sensor and a detection magnet fixedly attached to said trigger for determining the position of said trigger.

9. The device according to claim 8, further comprising a second Hall effect sensor, said first and second sensors being distant from each other along a trajectory of movement of said trigger.

10. The device according to claim 9 wherein said first Hall effect sensor is of the analog type and said second Hall effect sensor is of a digital or analog type.

11. The device according to claim 1 wherein said first and second rotation frequencies are of the same sign or of opposite signs.

12. The device according to claim 1 wherein said first and second rotation frequencies have equal or different standards.
